(19) United States
(12) Patent Application Publication
(10) Pub. No.: US 2019/0146547 A1
(43) Pub. Date: May 16, 2019

(54) SEMICONDUCTOR INTEGRATED CIRCUIT DEVICE

(71) Applicant: DENSO CORPORATION, Kariya-city (JP)

(72) Inventor: Shinichiro NAKATA, Kariya-city (JP)

(21) Appl. No.: 16/244,174

(22) Filed: Jan. 10, 2019

Related U.S. Application Data
(63) Continuation of application No. PCT/JP2017/045321, filed on Dec. 18, 2017.

(30) Foreign Application Priority Data
Feb. 28, 2017 (JP) 2017-36561

(51) Int. Cl. G06F 1/06; H03K 5/133; G06F 1/26; G06F 11/30; G06F 11/34

(52) U.S. Cl. CPC G06F 1/06; H03K 5/133; H03K 2005/00234; G06F 11/3013; G06F 11/349; G06F 1/26

(57) ABSTRACT

A semiconductor integrated circuit device comprises a first oscillation circuit which is supplied with an external DC power and generates a first clock, a power supply circuit which is supplied with the external DC power and outputs a DC voltage by a switching operation based on the first clock, a second oscillation circuit which generates a second clock, a load circuit which is supplied with the output DC voltage and operates based on the second clock, a monitor which monitors an operation of the first oscillation circuit based on the second clock under a state that the first and second oscillation circuits are in operation, and a switch circuit which switches to supply the power supply circuit with the second clock in place of the first clock when the monitor circuit detects a failure of the first oscillation circuit.

### CROSS REFERENCE TO RELATED APPLICATION

This application is a continuation application of International Patent Application No. PCT/JP2017/045321 filed on Dec. 18, 2017, which designated the U.S. and claims the benefit of priority from Japanese Patent Application No. 2017-36561 filed on Feb. 28, 2017. The entire disclosures of all of the above applications are incorporated herein by reference.

### FIELD

The present disclosure relates to a semiconductor integrated circuit device.

### BACKGROUND

In a semiconductor IC (integrated circuit) such as a microcomputer which operates with one power supply voltage, two oscillators mounted outside and inside the semiconductor IC are monitored mutually. As a result, when there is a halt or runaway of one oscillator, it is possible to back up the operation of the microcomputer by switching an oscillator from one oscillator to the other oscillator when one oscillator fails.

### SUMMARY

A semiconductor integrated circuit device is provided with a first oscillation circuit, a power supply circuit, a second oscillation circuit, a load circuit, a monitor circuit and a switch circuit. The first oscillation circuit is configured to generate, with power supplied from an external power supply source, a first clock. The power supply circuit is configured to generate, with the power supplied from the external power supply, an output DC voltage by a switching operation based on the first clock. The second oscillation circuit is configured to generate a second clock. The load circuit is configured to operate, with the output DC voltage, based on the second clock. The monitor circuit is configured to monitor an operation of the first oscillation circuit based on the second clock in a state of operations of the first oscillation circuit and the second oscillation circuit. The switch circuit is configured to switch a dock supplied the power supply circuit from the first clock to the second dock when the monitor circuit detects an abnormality of the first oscillation circuit.

### BRIEF DESCRIPTION OF THE DRAWINGS

FIG. 1 is an electric block diagram showing a semiconductor integrated circuit device according to a first embodiment;

FIG. 2 is an electrical block configuration diagram of a clock monitor circuit in the first embodiment;

FIG. 3 is an electrical configuration diagram showing one example of the clock monitor circuit shown in FIG. 2;

FIG. 4 is a flowchart of a monitoring operation executed in the first embodiment;

FIG. 5 is a time chart showing a signal state of each part of the clock monitor circuit in the first embodiment;

FIG. 6 is an electric block diagram showing a semiconductor integrated circuit device according to a second embodiment;

FIG. 7 is an electrical configuration diagram showing a clock monitor circuit in the second embodiment;

FIG. 8 is a flowchart of a monitoring operation executed in the second embodiment;

FIG. 9 is a time chart showing a signal state of each part of the clock monitor circuit shown in the second embodiment;

FIG. 10 is an electric block diagram showing a semiconductor integrated circuit device according to a third embodiment;

FIG. 11 is an electric block diagram showing a semiconductor integrated circuit device according to a fourth embodiment;

FIG. 12 is an electric block diagram showing a semiconductor integrated circuit device according to a fifth embodiment;

FIG. 13 is a block diagram showing a semiconductor integrated circuit device according to a sixth embodiment; and

FIG. 14 is an electrical configuration diagram showing a different example of a clock monitor circuit of a semiconductor integrated circuit device according to a seventh embodiment.

### EMBODIMENT FOR CARRYING OUT THE INVENTION

### First Embodiment

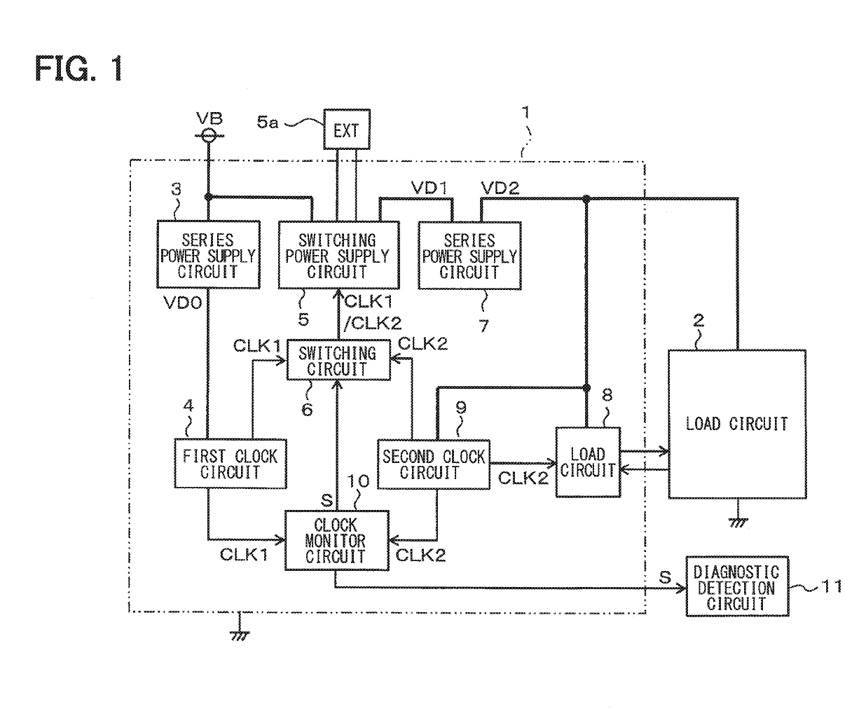

A first embodiment, which is applied to a semiconductor integrated circuit device for a vehicle, will be described with reference to FIG. 1 to FIG. 5.

FIG. 1 shows an entire block configuration, in which a power supply system is indicated by a bold solid line and a signal system is indicated by a thin solid line. A semiconductor IC 1 as a semiconductor integrated circuit device is configured to be supplied with power from an in-vehicle battery VB, which is an external DC power supply source, and supply an external load circuit 2 with a predetermined voltage. Further, the semiconductor IC 1 has a function of monitoring an operation state of the load circuit 2.

In the semiconductor IC 1, a series power supply circuit 3 is supplied with power from the in-vehicle battery VB. It generates a predetermined DC voltage VD0, and supplies power to a first clock circuit 4 which functions as a first oscillation circuit. The first clock circuit 4 starts its operation when the DC voltage VD0 is supplied and outputs a first clock CLK1 of a predetermined frequency. A switching power supply circuit 5 functions as a power supply circuit or a first power supply circuit. It is supplied with power from the in-vehicle battery VB and the first clock CLK1 from the first clock circuit 4 via a switch circuit 6.

In the switching power supply circuit 5, a switching element provided internally is driven and controlled by the first clock CLK1 supplied from the first clock circuit 4 thereby generating a first predetermined DC voltage VD1. It is to be noted that the switching power supply circuit 5 is configured together with an externally attached circuit 5a provided with an externally provided coil or the like. Further, in the switching power supply circuit 5, a capacitance of a capacitor provided in an output stage is adjusted so that, even when the first clock CLK1 becomes unavailable, an output voltage may be maintained continuously for a certain period of time corresponding to a predetermined number of clocks. This capacitor may be provided in the external circuit 5a.

A series power supply circuit 7 functions as a power supply circuit or a second power supply circuit. It generates a second predetermined DC voltage VD2 as an output DC voltage based on the DC voltage VD1 supplied from the switching power supply circuit 5. The series power supply circuit 7 supplies the DC voltage VD2 to the external load circuit 2, an internal load circuit 8 and a second clock circuit 9 which functions as a second oscillation circuit. The second clock circuit 9 starts its operation when the DC voltage VD2 is supplied and outputs a second clock CLK2 of a predetermined frequency. The second clock circuit 9 also supplies the second clock CLK2 to the switch circuit 6. The load circuit 8 in the semiconductor IC 1 is a watchdog timer circuit, for example, which monitors the operation of the external load circuit 2 by the second clock CLK2 supplied from the second clock circuit 9.

A clock monitor circuit 10 is provided to monitor an operation of the first clock circuit 4. It receives the first clock CLK1 from the first clock circuit 4 and the second clock CLK2 from the second clock circuit 9. The clock monitor circuit 10 starts a monitoring operation when the first clock circuit 4 and the second clock circuit 9 are activated. When the first clock CLK1 fails, the clock monitor circuit 10 outputs a abnormality detection signal S from an output terminal OUT to the switch circuit 6. Upon receiving the detection signal S from the clock monitor circuit 10, the switch circuit 6 performs a switching operation so as to output the second clock CLK2 to the switching power supply circuit 5 in place of the first clock CLK1.

Further, the clock monitor circuit 10 outputs the detection signal 5, which is outputted from an output terminal OUT when the first clock CLK1 fails, to a diagnostic detection circuit 11 provided outside the semiconductor IC 1. When the detection signal S is inputted, the diagnosis detection circuit 11 recognizes that the first clock circuit 4 has failed.

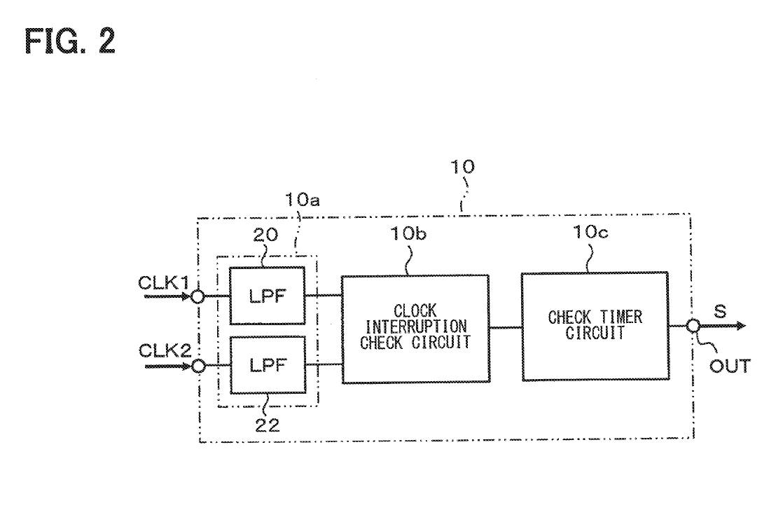

FIG. 2 shows an electrical block configuration diagram of the clock monitor circuit 10. The clock monitor circuit 10 includes a filter circuit 10a, a clock interruption check circuit 10b, and a check timer circuit 10c. The first clock CLK1 and the second clock CLK2 are input to the clock interruption check circuit 10b via the filter unit 10a. When the first clock CLK1 is interrupted, the clock interruption check circuit 10b detects this interruption and outputs it to the check timer circuit 10c. The check timer circuit 10c outputs the detection signal S when the interruption state of the first clock CLK1 continues for a predetermined period.

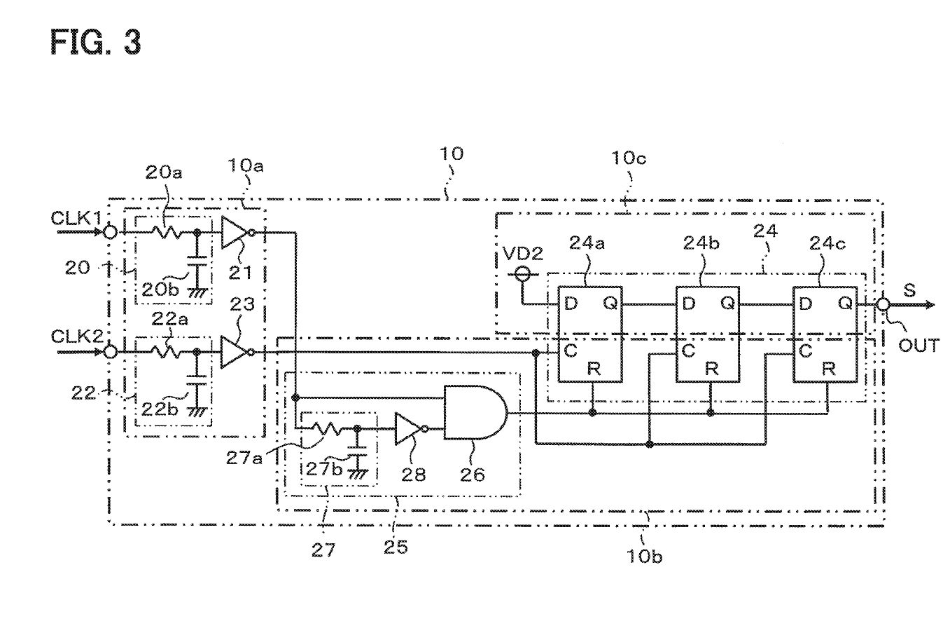

FIG. 3 shows a detailed electrical configuration of the dock monitor circuit 10. At an input portion of the first clock CLK1, a filter circuit 20 and an inverter 21 are provided. The filter circuit 20 is a low-pass filter (LPF) formed of a resistor 20a and a capacitor 20b. Similarly, at an input portion of the second clock CLK2, a filter circuit 22 and an inverter 23 are provided. The filter circuit 22 is a low-pass filter (LPF) formed of a resistor 22a and a capacitor 22b. The filter circuits 20, 22 and the inverters 21, 23 form a filter circuit 10a.

Three D-type flip-flop circuits (hereinafter referred to as DFF) 24a to 24c, which are latch circuits, are connected in cascade and provided as a counter circuit 24. The DC power supply voltage VD2 is connected to a D input terminal of the DFF 24a. An output terminal of the inverter 23 is connected to a C input terminal of the DFF 24a. A Q output terminal of the DFF 24a is connected to a D input terminal of the DFF 24b. A Q output terminal of the DFF 24b is connected to a D input terminal of the DFF 24c. A Q output terminal of the DFF 24c is connected to the output terminal OUT of the counter circuit 24, which is the output terminal OUT of the clock monitor circuit 10.

An output terminal of the inverter 21 is connected to each reset terminal R of the DFFs 24a to 24c via a pulse generation circuit 25. The pulse generation circuit 25 is configured to output a constant pulse when the first clock circuit 4 is normal. The pulse generation circuit 25 is configured to be unable to reset the counter circuit 24 when the first clock circuit 4 becomes an abnormal state such as an oscillation state and generates the first clock CLK1 at a high frequency.

The pulse generation circuit 25 includes an AND circuit 26, a delay circuit 27 and an inverter 28. An output terminal of the inverter 21 is connected to one input terminal of the AND circuit 26 and also connected to the other input terminal of the AND circuit 26 via the delay circuit 27 and the inverter 28. The delay circuit 27 is formed of a resistor 27a and a capacitor 27b.

In the pulse generation circuit 25, in a state in which the first clock CLK1 is normally input, the AND circuit 26 outputs a high level signal at time when its input changes from a low level to a high level. Then, when the delay period set by the delay circuit 27 elapses, the output of the AND circuit 26 changes to a low level.

In the above-described configuration, a part of the counter circuit 24 and the pulse generation circuit 25 form the dock interruption check circuit 10b. In addition, the remaining portion of the counter circuit 24 forms the check timer circuit 10c.

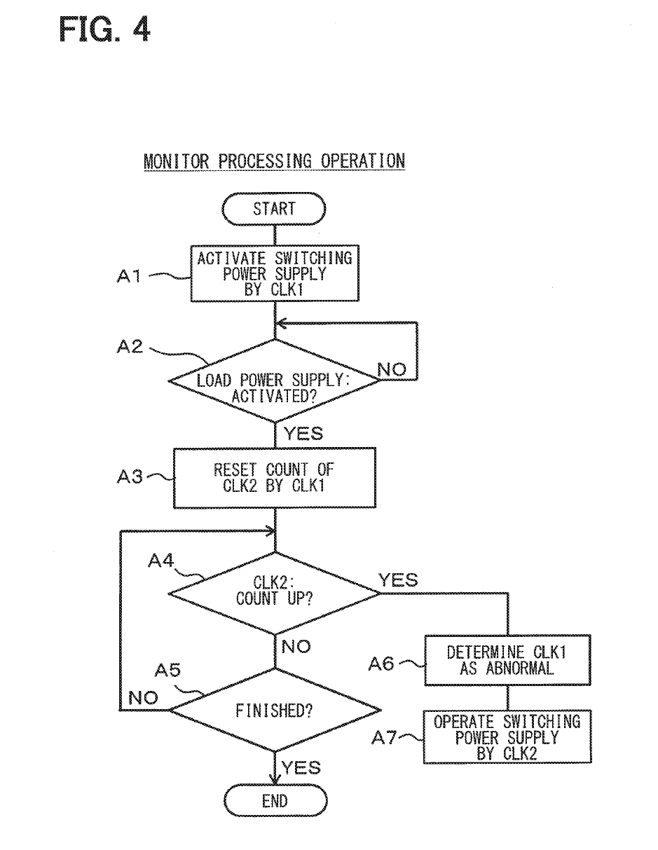

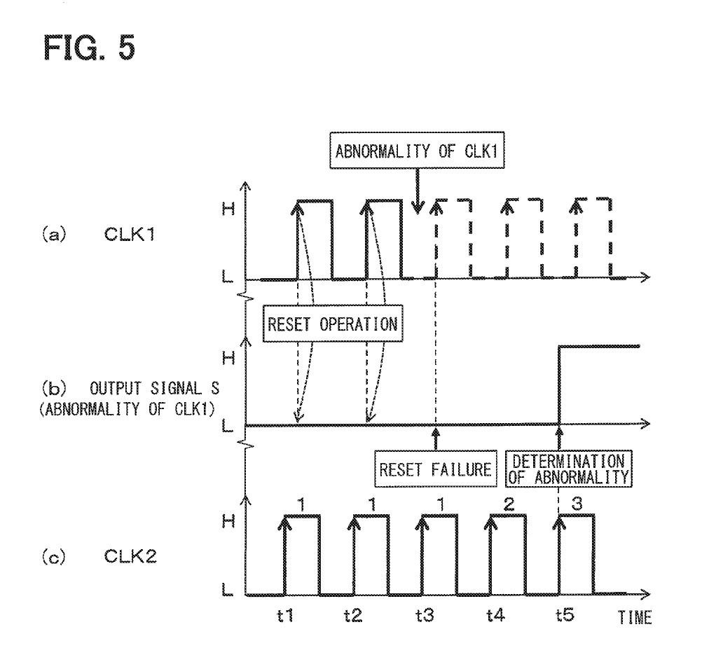

An operation of the above-described configuration will be described with further reference to FIG. 4 and FIG. 5. FIG. 4 shows a start and monitor contents of monitor processing operation by the clock monitor circuit 10, which will be described later, including the operation after the semiconductor IC 1 is powered.

When the external DC power is supplied from the in-vehicle battery VB to the semiconductor IC 1, the series power supply circuit 3 and the switching power supply circuit 5 are supplied with power first. The series power supply circuit 3 generates the predetermined DC voltage VD0 and supplies power to the first clock circuit 4. As a result, the first clock circuit 4 generates the first clock CLK1 and supplies it to the switching power supply circuit 5 via the switch circuit 6. The first clock circuit 4 also supplies the first clock CLK1 to the clock monitor circuit 10.

The switching power supply circuit 5 drives and controls internal switching elements thereof based on the first clock CLK1 to generate the predetermined DC voltage VD1 and outputs it to the series power supply circuit 7. This operation corresponds to step A1 in FIG. 4. In response to this DC voltage VD1, the series power supply circuit 7 generates the predetermined DC voltage VD2 to supply power to the load circuit 8 and the second clock circuit 9, and also to the load circuit 2 connected externally. This operation corresponds to step A2 in FIG. 4.

When the DC voltage VD2 is supplied, the second clock circuit 9 generates the second clock CLK2 and supplies it to the load circuit 8. The second clock circuit 9 further supplies the second clock CLK2 to the clock monitor circuit 10 and the switch circuit 6. As a result, the load circuit 8 performs a function as a watchdog timer circuit based on the second clock CLK2, and monitors the operation state of the external load circuit 2.

With a post-activation operation described above, the clock monitor circuit 10 starts a monitoring operation when the first clock circuit 4 and the second clock circuit 9 are activated. As an operation corresponding to step A3 in FIG. 4, the clock monitor circuit 10 monitors an output state of the first clock CLK1 of the first clock circuit 4.

Since the DC voltage VD2 is supplied to the D input terminal of the DFF 24a, the counter circuit 24 is in the input state of a high level “H.” In addition, since the second clock CLK2 is supplied to the C input terminal of each of the DFFs 24a to 24c, the counter circuit 24 outputs the detection signal S of the high level after counting three pulses of the second clock CLK2 in the absence of a reset input. However, since data of the Q output terminals of the DFFs 24a to 24c are reset to low levels “L” during a period when the first clock CLK1 is input to the reset terminals R in a period between time t1 and time t2 in FIG. 5, the detection signal S is maintained at the low level state.

Since this state corresponds to a state in which the second clock CLK2 is not counted up in step A4 of FIG. 4, a check result in step S4 is NO. In the state where the operation is continued, a check result in step AS is also NO. Thus, steps A4 and AS are repeatedly executed until the operation is finished.

However, in case that the operation of the first clock circuit 4 becomes abnormal, the first clock CLK1 is not normally output. For example, as shown in (a) of FIG. 5, when the first clock circuit 4 stops the oscillation because of the abnormal operation after time t3 and the first clock CLK1 disappears from the third one as indicated by a dotted line, the counter circuit 24 is not reset any more. As a result, the counter circuit 24 counts clock pulses of the second clock CLK2. As a result, at time t5 at which the third clock pulse is input from time t3 of the count start as shown in (c) of FIG. 5, the detection signal S of the high level is output as shown in (b) of FIG. 5.

In this case, the clock monitor circuit 10 executes step A6 with a check result YES in step A4 in FIG. 4, determines that the first clock CLK1 is in an abnormal state, and outputs the detection signal S of the high level indicating detection of the abnormal state. In response to this high level detection signal 5, the switch circuit 6 switches the switching power supply circuit 5 from a state of supplying the first clock CLK1 to a state of supplying the second clock CLK2 in step A7.

When an abnormality is detected as described above, the detection signal S is also output from the clock monitor circuit 10 to the external diagnostic detection circuit 11 as well. As a result, the diagnostic detection circuit 11 warns a driver on a display unit inside a vehicle by, for example, displaying the state of occurrence of abnormality in the first clock circuit 4.

The switching power supply circuit 5 cannot output the predetermined DC voltage VD1 because the first clock CLK1 is not generated and its operation is disabled during a power generation operation. However, with a capacitor (not shown) provided in the output stage of the switching power supply circuit 5, the output voltage is maintained for a fixed period until switching of the clocks so that circuit operations in the subsequent stages can be maintained.

Therefore, the clock monitor circuit 10 detects an abnormality during a period in which three second clocks CLK2 are counted from time when generation of the first clock CLK1 is stopped, and switches the switching power supply circuit 5 to generate the power based on the second clock CLK2 in a short period. Thus, in the switching power supply circuit 5, the power supply operation can be continuously performed even in a state in which the operation of the first clock circuit 4 is stopped.

As a result, the semiconductor IC 1 can continuously operate in a state in which power is supplied from the in-vehicle battery VB. Therefore, in case where the semiconductor IC 1 supplies the power for driving the load circuit 2 which controls driving of the vehicle for example, it is possible to continuously control the driving of the vehicle during a period until the power supply from the battery VB is stopped even if the abnormality of the first clock circuit 4 occurs. Thus, even when a failure occurs, it is possible to perform evacuation procedures such as moving the vehicle to a safe place.

In addition to the above-exemplified case, when the frequency of the first clock CLK1 becomes abnormally high due to an abnormal oscillation state or the like of the first clock circuit 4, the output level of the delay circuit 27 is fixed to the high level “H” and the output level of the inverter 28 is fixed to the low level “L” in response to the fixed high level output in the pulse generation circuit 25. Therefore, in the AND circuit 26, even when one of input signals changes at “H” level and “L” level at a high frequency, the other input signal is fixed at the low level “L” so that the counter circuit 24 is maintained in a state not to be reset.

As a result, the counter circuit 24 is in the same state as when generation of the first dock CLK1 is stopped as described above, and the detection signal S is outputted when three pulses of the second dock CLK2 are counted. Thus, the switch circuit 6 supplies the second dock CLK2 to the switching power supply circuit 5, the operation state of the semiconductor IC 1 is maintained to enable the continued operation of the load circuit 2 until the power supply is stopped and the operation is finished.

When the semiconductor IC 1 is next supplied with power from the in-vehicle battery VB, it is not possible to drive the switching power supply circuit 5 because the first dock circuit 4 has failed. The power supply to the load circuit 2 is thus disabled and the drive control of the vehicle cannot be performed. However, in this case, since it is in a state before starting to drive the vehicle, it is possible to notify the driver of the state where driving cannot be performed by displaying the occurrence of abnormality on the display section inside the vehicle.

According to the first embodiment as described above, the semiconductor IC 1 is configured to include therein the first clock circuit 4 and the second clock circuit 9 which is operated with the power supply generated based on the first clock CLK1. Further, the semiconductor IC 1 is configured to include the clock monitor circuit 10 which monitors the first clock CLK1 by the second clock CLK2. Thus, when the abnormality of the first clock circuit 4 is detected by the clock monitor circuit 10, the switching power supply circuit 5 is operated by the second clock CLK2. As a result, the operation of the switching power supply circuit 5 can be continued in the state where the semiconductor IC 1 is in operation and monitoring the external load circuit 2 can also be continued.

In addition, since the filter circuits 20 and 22 are provided, even when the frequency of the first clock CLK1 becomes high because of the abnormal oscillation of the first clock circuit 4, it is possible to detect the abnormal state of the first clock circuit 4 by the clock monitor circuit 10 and switch the clock to the second clock CLK2.

Accuracy of the first clock CLK1 of the first clock circuit 4 is set relatively high in order to secure output accuracy of the switching power supply circuit 5. Accuracy of the second clock CLK2 of the second clock circuit 9 may be lower, as far as the switching power circuit 5 can ensure power supply required by the subsequent stages.

### Second Embodiment

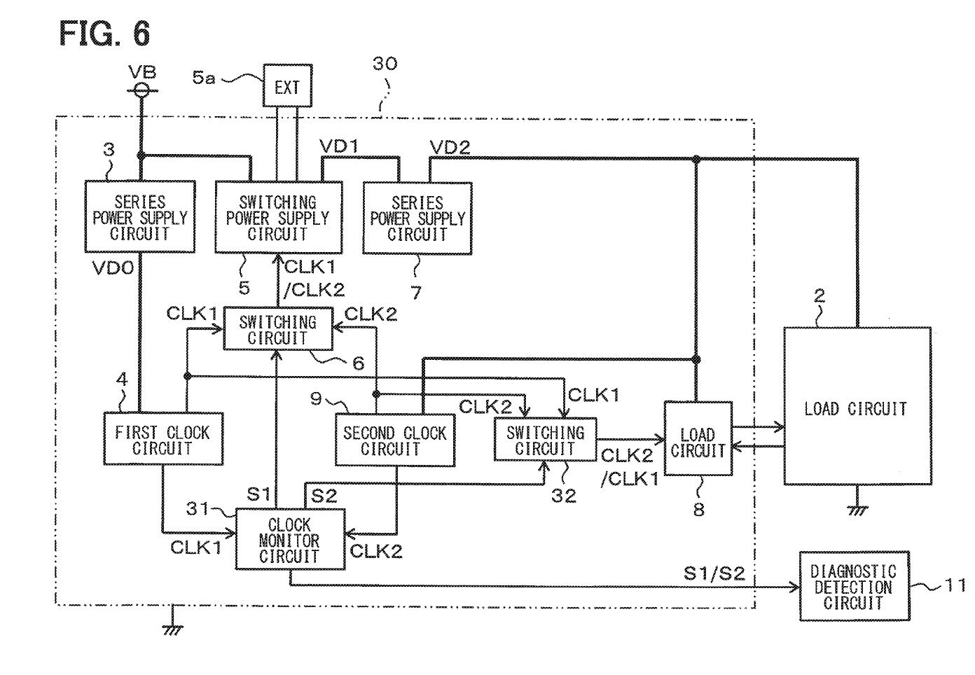

FIG. 6 to FIG. 9 show a second embodiment. Its differences from the first embodiment will be described below. In the second embodiment, the operation of the second clock circuit 9 is also monitored at the same time by the first clock CLK1. As a result, the first clock circuit 4 and the second clock circuit 9 are mutually monitored.

As shown in FIG. 6, a semiconductor IC 30 as a semiconductor integrated circuit device is provided with a clock monitor circuit 31 in place of the clock monitor circuit 10 and newly with a switch circuit 32. The switch circuit 32 receives the first clock CLK1 from the first clock circuit 4 and the second clock CLK2 from the second clock circuit 9. Further, the switch circuit 32 normally supplies the second clock CLK2 to the load circuit 8. Further, the switch circuit 32 supplies the first clock CLK1 to the load circuit 8 when an abnormality detection signal S2 is input from the clock monitor circuit 31. Here, the switch circuit 6 functions as a first switch circuit and the switch circuit 32 functions as a second switch circuit.

It is noted that, although the load circuit 8 is configured to perform monitoring the operation of the load circuit 2 based on the second clock CLK2 input from the second clock circuit 9, the load circuit 8 is configured to be not affected in its monitoring operation even if the second clock CLK2 loses several pulses during the monitoring operation. The load circuit 8 is configured to be able to continue the monitoring operation by shifting to a state where the first clock CLK1 is supplied after a predetermined number of clock pulses from the failure of the second clock circuit 9.

The clock monitor circuit 31 is configured to monitor operations of the first clock circuit 4 and the second clock circuit 9 mutually. It receives the first clock CLK1 from the first clock circuit 4 and the second clock CLK2 from the second clock circuit 9. The clock monitor circuit 31 starts a monitoring operation described later when the first clock CLK1 and the second clock CLK2 are supplied.

When the first clock CLK1 becomes abnormal, the clock monitor circuit 31 outputs a detection signal 51 from an output terminal OUT1 to the switch circuit 6. Upon receiving the detection signal Si from the clock monitor circuit 31, the switch circuit 6 performs a switching operation so as to output the second clock CLK2 to the switching power supply circuit 5. When the second clock CLK2 becomes abnormal, the clock monitor circuit 31 outputs a detection signal S2 from an output terminal OUT2 to the switch circuit 32. Upon receiving the detection signal S2 from the clock monitor circuit 31, the switch circuit 32 performs a switching operation so as to output the first clock CLK1 to the load circuit 8.

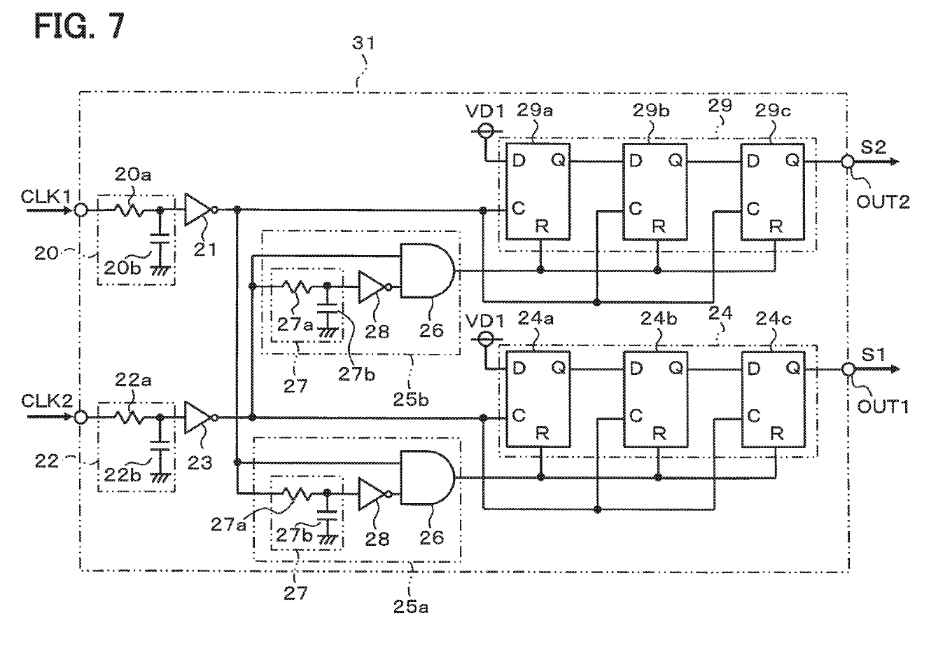

FIG. 7 shows an electrical configuration of the clock monitor circuit 31. In this configuration, as counterparts to the clock monitor circuit 10 provided in the first embodiment, in addition to the counter circuit 24, a counter circuit 29 and a pulse generation circuit 25b are newly added in addition to the counter circuit 24, the pulse generation circuit 25a and the like.

The pulse generation circuits 25a and 25b have the same configuration as the pulse generation circuit 25 provided in the first embodiment, and include the AND circuit 26, the delay circuit 27 and the inverter 28. The counter circuit 29 is a cascade connection of three DFFs 29a to 29c as latch circuits, and has the similar configuration as the counter circuit 24. The counter circuit 24 outputs the detection signal S1 from the Q output terminal of the DFF 24c via the output terminal OUT1. The counter circuit 29 outputs the detection signal S2 from the Q output terminal of the DFF 29c via the output terminal OUT2. The output terminal of the inverter 21 is connected to the C input terminal of the DFF 29a of the counter circuit 29.

The output terminal of the inverter 23 is connected to each reset terminal R of the DFFs 29a to 29c via the pulse generation circuit 25b. The pulse generation circuit 25b is configured to be unable to reset the counter circuit 29 when the second clock circuit 9 becomes an abnormal state such as an oscillation state and generates the second clock CLK2 at a high frequency.

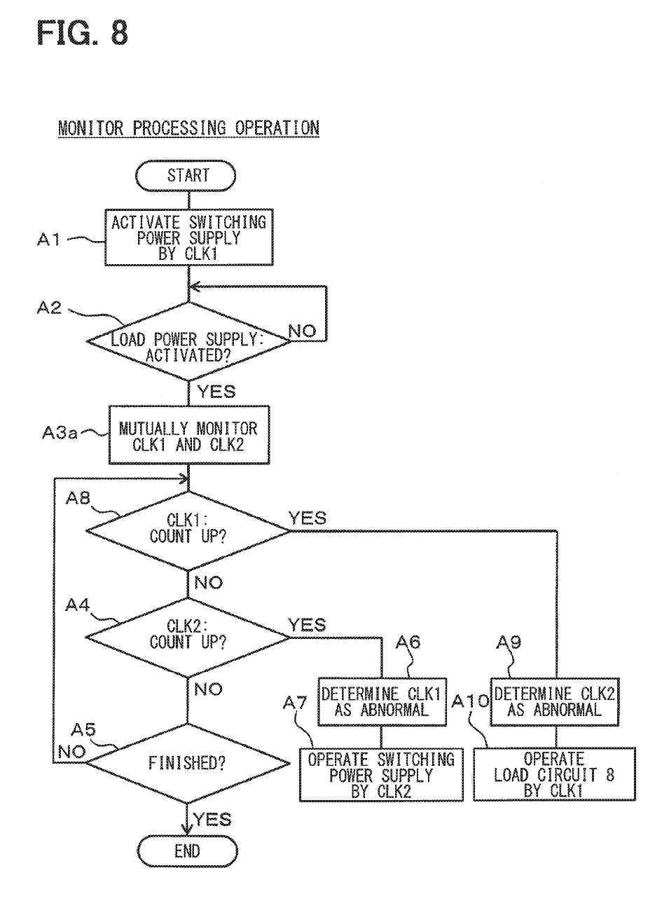

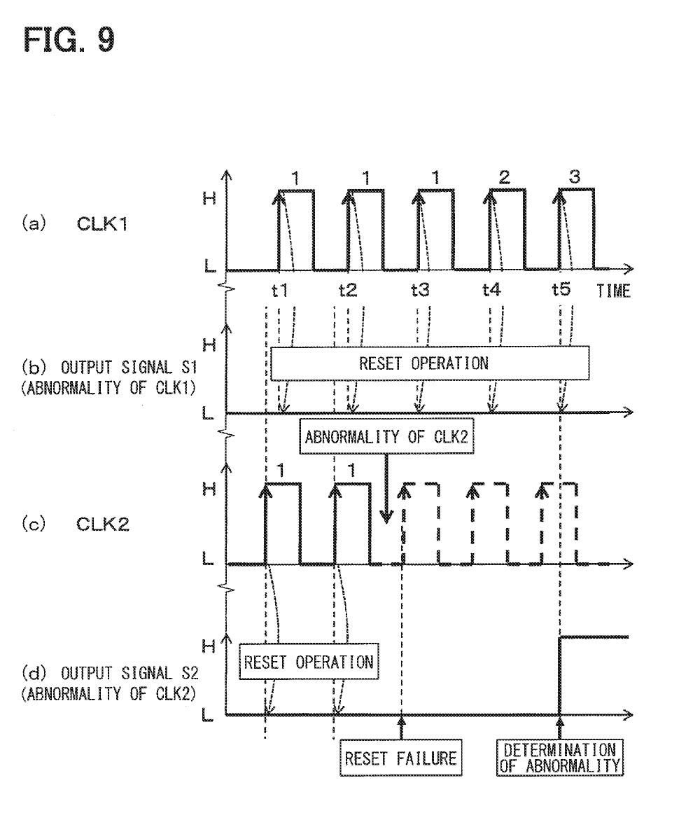

An operation of the above-described configuration will be described with further reference to FIG. 8 and FIG. 9. FIG. 8 shows a start and monitor contents of monitor processing operation by the clock monitor circuit 31, which will be described later, including the operation after the semiconductor IC 30 is powered.

The difference from the first embodiment is that, first, after executing steps A1 and A2, step A3a is executed in place of step A3. The semiconductor IC 30 starts its operation when the external DC power is supplied from the in-vehicle battery VB. After executing steps A1 and A2, the second clock signal CLK2 is input to the clock monitor circuit 31. Thereafter, the semiconductor IC 30 starts an operation of mutually monitoring the first clock CLK1 and the second clock CLK2 in step A3a. As a result, the load circuit 8 performs a function as a watchdog timer circuit based on the second clock CLK2, and monitors the operation state of the external load circuit 2.

With a post-activation operation described above, the clock monitor circuit 31 starts the mutual monitoring operation when the first clock circuit 4 and the second clock circuit 9 are activated. As an operation corresponding to step A3a in FIG. 8, the clock monitor circuit 31 mutually monitors output states of the first clock CLK1 of the first clock circuit 4 and the second clock CLK2 of the second clock circuit 9. In the clock monitor circuit 31, the monitoring operation on the first clock circuit 4 by the second clock CLK2 of the second clock circuit 9 is performed by the monitoring operation as described in the first embodiment. The detection signal from the counter circuit 24 is output from the output terminal OUT1 as the detection signal S1.

In the clock monitor circuit 31, the monitoring operation on the second clock circuit 9 by the first clock CLK1 of the first clock circuit 4 is performed. Since the DC power supply VD1 is applied to a D input terminal of the DFF 29a, the counter circuit 24 is inputted with the high level “H.” In addition, since the first clock CLK1 is supplied to the C input terminal of each of the DFFs 29a to 29c, the counter circuit 24 outputs the detection signal S2 of the high level after counting three pulses of the first clock CLK1 in the absence of a reset input. However, since data of the Q output terminals of the DFFs 29a to 29c are reset to low levels “L” during a period when the second clock CLK2 is input to the reset terminals R in a period between time t1 and time t2 in FIG. 9, the detection signal S2 is maintained at the low level state.

Since this state corresponds to a state in which the second clock CLK1 is not counted up in step A8 of FIG. 8, a check result in step A8 is NO. In the state where the operation is continued, a check result in step A5 is also NO. Thus, steps A8, A4 and A5 are repeatedly executed until the operation is finished.

However, in case that the operation of the second clock circuit 9 becomes abnormal, the second clock CLK2 is not normally output. For example, as shown in (c) of FIG. 9, when the second clock circuit 9 becomes abnormal and stops the oscillation after time t2 and the second clock CLK2 disappears from the third pulse, the counter circuit 29 is not reset any more. As a result, the counter circuit 29 counts clock pulses of the second clock CLK2. As a result, at time t5 at which the third clock pulse is input from time t3 of the count start as shown in (c) of FIG. 9, the detection signal S2 of the high level is output as shown in (b) of FIG. 9.

In this case, the clock monitor circuit 31 determines “YES” in step A8 in FIG. 8 and proceeds to step A9, determines that the second clock CLK 2 is in an abnormal state, and outputs the detection signal S2 of the high level indicating the abnormal state. In response to this high level detection signal S2, the switch circuit 32 switches from a state of supplying the second clock CLK2 to a state of supplying the first clock CLK1 in step A10.

When the abnormality is detected as exemplified above, a display device provided in a vehicle warns a driver by, for example, displaying the state of occurrence of abnormality in the second clock circuit 9.

As a result, the semiconductor IC 30 can continuously operate in a state in which power is supplied from the in-vehicle battery VB. Therefore, in case where the semiconductor IC 30 supplies the power for driving the load circuit 2 which controls driving of the vehicle for example, it is possible to continuously control the driving of the vehicle during a period until the power supply is stopped even if the abnormality of the second clock circuit 9 occurs. Thus, even when a failure occurs, it is possible to perform evacuation procedures such as moving the vehicle to a safe place.

In addition to the above-described case, even when the frequency of the second clock CLK2 becomes abnormally high due to the abnormal oscillation state or the like of the second clock circuit 9, the pulse generation circuit 25b operates to disable resetting of the counter circuit 29. As a result, the counter circuit 29 is in the same state as when the second clock CLK2 is stopped, and the detection signal S2 is output.

When the semiconductor IC 30 is next supplied with power from the in-vehicle battery VB, the first clock circuit 4 normally operates. Thus, the switching power supply circuit 5 is driven and power can be supplied to the load circuit 2. In this case, since the second clock circuit 9 is faulty, the abnormal state of the second clock circuit 9 is determined again by the clock monitor circuit 31 and the first clock CLK1 is input to the load circuit 8. As a result, the load circuit 8 is enabled to operate.

According to the second embodiment as well, the first clock CLK1 and the second clock CLK2 can be mutually monitored by the clock monitor circuit 31 as in the first embodiment. As a result, as far as the semiconductor IC 30 operates, the switching power supply circuit 5 and the load circuit 8 can continue respective operations, and the external load circuit 2 can continue its monitoring operation.

### Third Embodiment

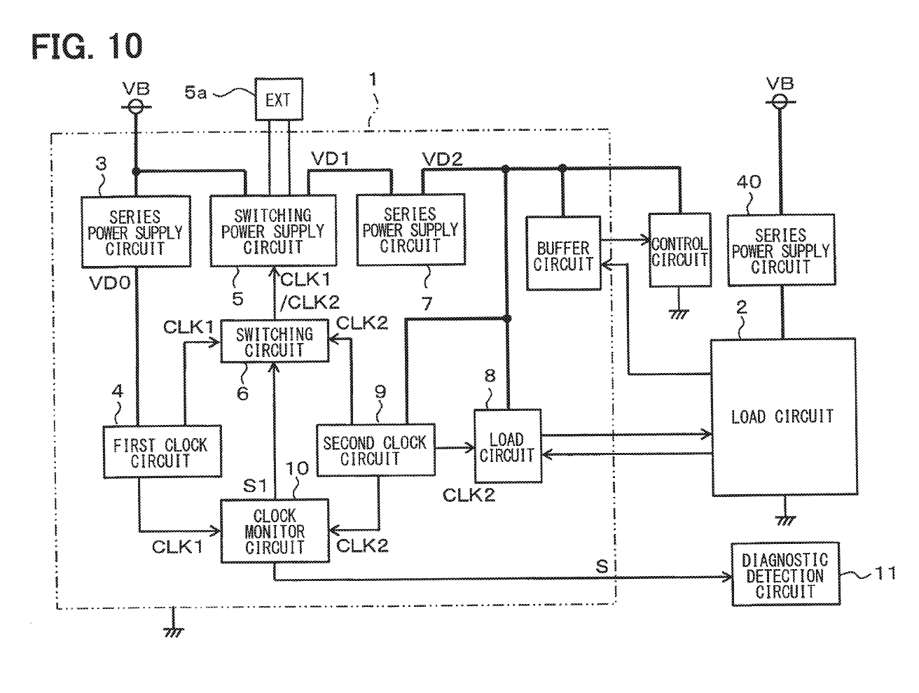

FIG. 10 shows a third embodiment. Its differences from the first embodiment will be described below. In the third embodiment, the semiconductor IC 1 does not supply power to the load circuit 2 provided externally. The load circuit 2 is configured to be supplied with power separately from the in-vehicle battery VB via a series power supply circuit 40. In this case, the operation state of the load circuit 2 is configured to be monitored by the load circuit 8 provided in the semiconductor IC 1 in the same manner as described above. In the semiconductor IC 1, the series power supply circuit 7 supplies power to not only the load circuit 8 and the second clock circuit 9 but also to other circuits such as a buffer circuit and a control circuit which need be supplied with power.

Thus, when the abnormality of the first clock circuit 4 is detected by the clock monitor circuit 10, the switching power supply circuit 5 is operated by the second clock CLK2. As a result, the operation of the switching power supply circuit 5 can be continued in the state where the semiconductor IC 1 is in operation and monitoring the external load circuit 2 can also be continued as in the first embodiment.

### Fourth Embodiment

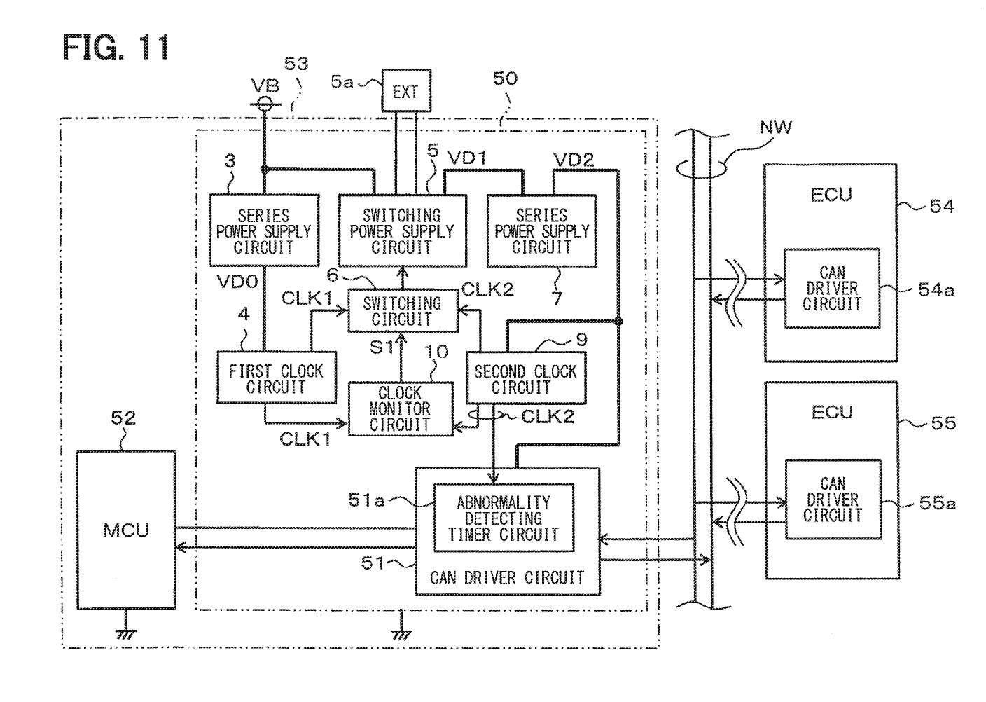

FIG. 11 shows a fourth embodiment. Its differences from the first embodiment will be described below. In the fourth embodiment, a semiconductor IC 50 having the similar configuration as the first embodiment is used. The semiconductor IC 50 includes a CAN (Controller Area Network) driver circuit 51 for communicating with a CAN communication network NW, which is a communication network in a vehicle, as a configuration corresponding to the load circuit 8.

The CAN driver circuit 51 has a configuration for carrying out CAN communication therein and an abnormality detecting timer circuit 51a for monitoring an internal state. The CAN driver circuit 51 operates by receiving the DC voltage VD2 from the series power supply circuit 7. The abnormality detecting timer circuit 51a is configured to use the second clock CLK2 input from the second clock circuit 9 as a clock for operation.

Upon receiving a communication signal from a MCU 52, the CAN driver circuit 51 outputs the received signal by converting the communication signal into a signal corresponding to the protocol of the CAN network NW and outputs a signal received from the CAN network NW by converting it to the MCU 52. The MCU 52 is provided as a configuration of the ECU 53 together with the semiconductor IC 50. To the CAN network NW, other ECUs 54 and 55 are connected. The other ECUs 54 and 55 are configured to be able to communicate through respective CAN driver circuits 54a and 55a.

In such a configuration, in the CAN driver circuit 51, in the same way as the load circuit 8 shown in the first embodiment, the abnormality detecting timer circuit 51a generates a CAN signal with the second clock CLK 2 supplied from the second clock circuit 9 and monitors an operation inside the driver circuit 51. When the CAN driver circuit 51 outputs a signal to the CAN network NW, the CAN driver circuit 51 performs control to occupy the network. Therefore, when the occupation state continues due to a failure, the CAN network NW becomes unusable. For this reason, the abnormality detecting timer circuit 51a detects an abnormal state of the operation of the CAN driver circuit 51 and operates so as to release the occupied state of the CAN network NW.

With the above-described configuration in the fourth embodiment, the same advantages as in the first embodiment can be provided.

Although the fourth embodiment is configured based on the configuration of the first embodiment, it may also be configured based on the configuration of the second embodiment.

### Fifth Embodiment

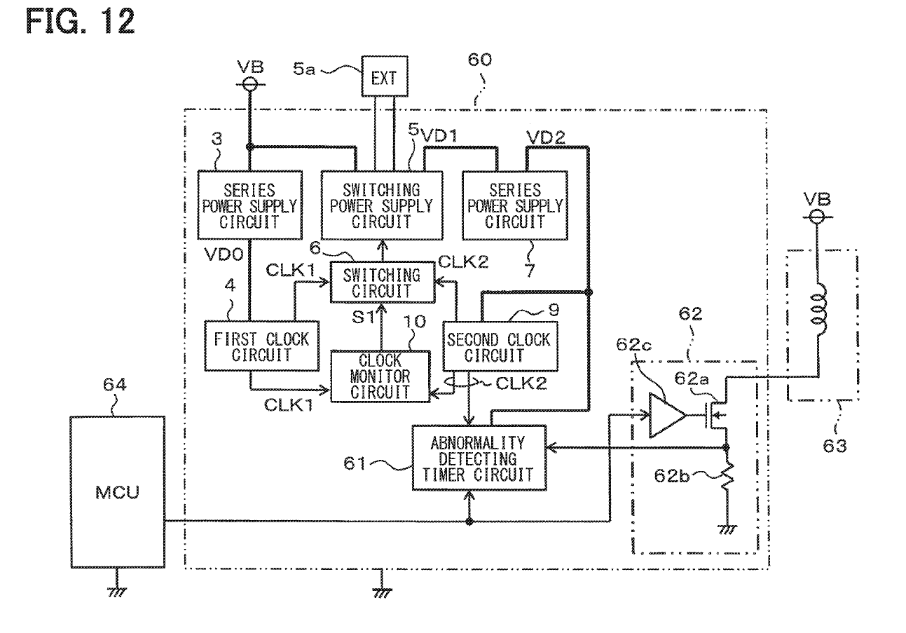

FIG. 12 shows a fifth embodiment. Its differences from the first embodiment will be described below. In the fifth embodiment, a semiconductor IC 60 having the similar configuration as the first embodiment is used. The semiconductor IC 60 is configured to include an abnormality detecting timer circuit 61 and an actuator drive circuit 62 as a configuration corresponding to the load circuit 8.

The abnormality detecting timer circuit 61 operates by receiving the DC voltage VD2 from the series power supply circuit 7. The abnormality detecting timer circuit 61 is configured to use the second clock CLK2 input from the second clock circuit 9 as a clock for operation. The abnormality detecting timer circuit 61 monitors an operation of the actuator drive circuit 62 based on the second clock CLK2.

The actuator drive circuit 62 performs drive control of the actuator 63 as a load circuit provided externally. The actuator drive circuit 62 is configured to supply power to the actuator 63 by a MOSFET 62a and detect current by a resistor 62b. When a gate drive signal is applied from an external MCU 64, the actuator drive circuit 62 applies a gate signal to the MOSFET 62a via a drive circuit 62c to perform on/off operation control for the MOSFET 62a.

The abnormality detecting timer circuit 61 monitors the current flowing through the actuator 63 from the a terminal voltage of the resistor 62a and monitors the gate drive signal from the MCU 64. The abnormality detecting timer circuit 61 monitors an actuator current corresponding to the gate drive signal based on the second clock CLK2.

With the above-described configuration in the fifth embodiment, the similar advantages as in the first embodiment can be provided.

Although the fifth embodiment is configured based on the first embodiment, it may be also be configured based on the second embodiment.

### Sixth Embodiment

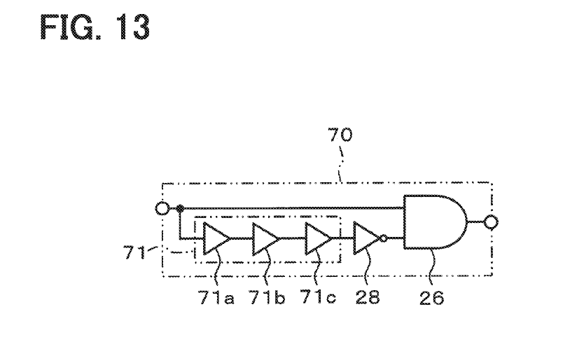

FIG. 13 shows a sixth embodiment. Its differences from the first embodiment will be described below. In the sixth embodiment, a pulse generation circuit 70 is provided in place of the pulse generation circuit 25 provided in the first embodiment.

The pulse generation circuit 70 includes a delay circuit 71 in place of the delay circuit 27. The delay circuit 71 has a configuration in which a plurality of, for example three, buffer circuits 71a to 71c are connected in series to thereby generate a delay period.

With the above-described configuration in the sixth embodiment, the similar advantages as in the first embodiment can be provided.

### Seventh Embodiment

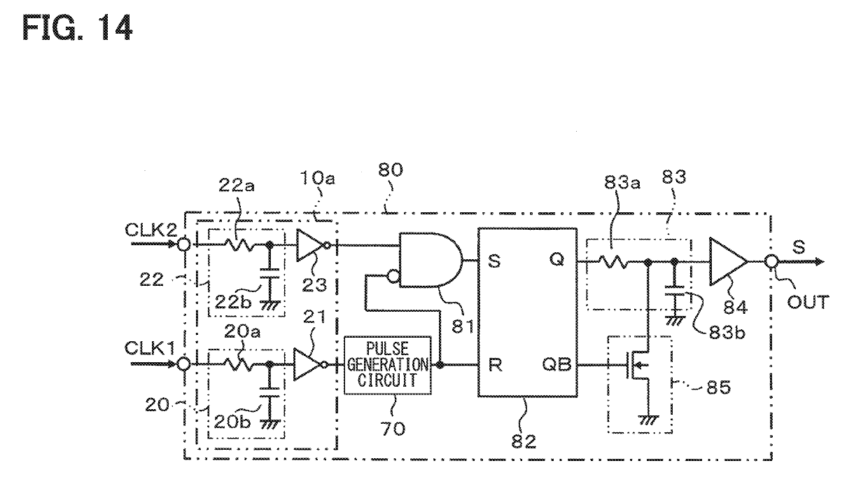

FIG. 14 shows a seventh embodiment. Its differences from the first embodiment will be described below. In the seventh embodiment, a clock monitor circuit 80 is used in place of the clock monitor circuit 10 provided in the first embodiment.

The clock monitor circuit 80 is provided with the filter 10a similar to that of the first embodiment at the input stage of the first clock CLK1 and the second clock CLK2. That is, the filter circuit 20 and the inverter 21 are provided at the input stage of the first clock CLK1, and the filter circuit 22 and the inverter 23 are provided at the input stage of the second clock CLK2. In FIG. 14, positions of indication of the first clock CLK1 and the second clock CLK2 are reversed relative the positions shown in the first embodiment.

The output terminal of the inverter 23 is connected to one input terminal of an AND circuit 81 and is connected to a set terminal S of a RS flip-flop circuit 82 provided as a latch circuit via an output terminal of the AND circuit 81. The output terminal of the inverter 21 is connected to a reset terminal R of the RS flip-flop circuit 82 through a pulse generation circuit 70 provided in the sixth embodiment and is also connected to the other inverting input terminal of the AND circuit 81. Here, the AND circuit 81 is provided to prioritize the reset input to the RS flip-flop 81 when the first clock CLK1 and the second clock CLK2 simultaneously become high level.

An output terminal Q of the RS flip-flop circuit 82 is connected to the output terminal OUT via a time constant circuit 83 and a buffer circuit 84. The time constant circuit 83 is formed of a resistor 83a and a capacitor 83b. An N-channel type MOSFET 85 is connected to a capacitor 83b thereby to provide a discharge path. An output terminal QB of the RS flip-flop 82 is connected to a gate of the MOSFET 85.

According to the above-described configuration, in a state in which both the first clock CLK1 and the second clock CLK2 are normally input, the RS flip-flop 82 changes between high level and low level at the clock cycle period. As a result, in the time constant circuit 83, the capacitor 83b is discharged by the MOSFET 85 before it is charged to a full charge level with the high level output from the output terminal Q. As a result, the buffer circuit 84 maintains the low level output state, that is, the detection signal S to be low.

On the other hand, when the first clock CLK1 is interrupted, the level of the output terminal Q is maintained at the high level. As a result, the terminal voltage of the capacitor 83b rises and the high level detection signal S is output from the buffer circuit 84. In addition, when the first clock CLK1 is brought into the oscillation state, the output of the pulse generation circuit 70 is maintained also at the low level. As a result, by operating in the same manner as described above, the buffer circuit 84 outputs the high level detection signal S.

With the above-described configuration in the seventh embodiment, the similar advantages as in the first embodiment can be provided.

### Other Embodiment

The present disclosure should not be limited to the embodiments described above. Various embodiments may further be implemented without departing from the scope of the present disclosure, and may be modified or expanded as described below.

In each of the above-described embodiments, the in-vehicle battery is used as the external DC power supply, but other power supply may be used as long as it is an external DC power supply.

In addition, although the series power supply circuit 3 is provided to convert the in-vehicle battery voltage VB into the predetermined voltage and supply it to the first clock circuit 4, the external DC power supply may alternatively be directly supplied to the first clock circuit 4.

Although the DC voltage VD1 output from the switching power supply circuit 5 is converted into the DC voltage VD2 as the output DC voltage by the series power supply circuit 7, the DC voltage VD2 may be generated as the output DC voltage directly by the switching power supply circuit 5 without using the series power supply circuit 7 and supplied to the load circuit 8 and the second clock circuit 9.

Although the load circuit 8 and the second clock circuit 9 are used as loads of the series power supply circuit 7, further load circuits may be provided.

In the clock monitoring circuits 10 and 31, the counter circuits 24 and 29 are configured as the latch circuits by using the DFFs 24a to 24c or the DFFs 29a to 29c, other latch circuits may be used and the number of stages of the DFFs may be varied.

The pulse generation circuits 25, 25a and 25b may adopt other logic circuit or a configuration that makes a software-like determination.

Although the first clock circuit 4 and the second clock circuit 9 are preferably configured to generate the clocks of substantially same frequency, which enable simple switching by the switch circuit 6 or 32, the clocks may be generated at different frequencies. In this case, when switching to the other clock by the switch circuit 6 or 32, the switching may be performed by providing a circuit for adjusting the frequency.

Although the present disclosure has been made in accordance with the embodiments, it is understood that the present disclosure is not limited to such embodiments and structures. The present disclosure covers various modification examples and equivalent arrangements. Furthermore, various combinations and formations, and other combinations and formations including one or more than one or less than one element may be made within the scope and the spirit of the present disclosure.

What is claimed is:

1. A semiconductor integrated circuit device comprising:
a first oscillation circuit configured to generate, with power supplied from an external power supply source, a first clock;
a power supply circuit configured to generate, with the power supplied from the external power supply, an output DC voltage by a switching operation based on the first clock;
a second oscillation circuit configured to generate a second clock;
a load circuit configured to operate, with the output DC voltage, based on the second clock;
a monitor circuit configured to monitor an operation of the first oscillation circuit based on the second clock in a state of operations of the first oscillation circuit and the second oscillation circuit; and
a switch circuit configured to switch a clock supplied the power supply circuit from the first clock to the second clock when the monitor circuit detects an abnormality of the first oscillation circuit.

2. The semiconductor integrated circuit device according to claim 1, wherein:
the power supply circuit includes a first power supply circuit and a second power supply circuit;
the first power supply circuit is configured to generate a DC voltage by a switching operation based on the first clock; and
the second power supply circuit is configured to convert the DC voltage generated by the first power supply circuit to the output DC voltage.

3. The semiconductor integrated circuit device according to claim 1, wherein:
the monitor circuit is configured to monitor further an operation of the second oscillation circuit based on the first clock;
the switch circuit is provided as a first switch circuit; and
a second switch circuit is provided to switch a clock supplied to the load circuit from the second clock to the first clock when the monitor circuit detects an abnormality of the second oscillation circuit.

4. The semiconductor integrated circuit device according to claim 1, wherein:
the second oscillation circuit is configured to operate with the output DC voltage supplied from the power supply circuit.

5. The semiconductor integrated circuit device according to claim 1, wherein:
the monitor circuit is configured to include a latch circuit.

6. The semiconductor integrated circuit device according to claim 1, wherein:
the monitor circuit is configured to include a CR filter.

7. The semiconductor integrated circuit device according to claim 1, wherein:
the second oscillation circuit is configured to generate the second clock in a range of accuracy sufficient for the power supply circuit to generate the output DC voltage relative to that of the first clock of the first clock generation circuit.

8. The semiconductor integrated circuit device according to claim 1, wherein
the second oscillation circuit is configured to supply the second clock to a watchdog timer circuit which is provided internally or externally.

9. The semiconductor integrated circuit device according to claim 1, wherein:
the second oscillation circuit is configured to supply the second clock to an abnormality detecting timer circuit which is provided in a communication circuit provided as the load circuit.

10. The semiconductor integrated circuit device according to claim 1, wherein:
the second oscillation circuit is configured to supply the second clock to an abnormality detecting timer circuit which is provided in an actuator drive circuit provided as the load circuit.
